(19) United States
(12) Patent Application Publication
(10) Pub. No.: US 2009/0289694 A1
(43) Pub. Date: Nov. 26, 2009

(54) Current-Sensing Apparatus and Method for Current Sensing

(76) Inventors: Gotthard Rieger, Erlangen (DE); Richard Schmidt, Baiersdorf (DE); Roland Weiss, Erlangen (DE)

Correspondence Address: HARNESS, DICKEY & PIERCE, P.L.C., P.O.BOX 8910, RESTON, VA, 20195, US

(21) Appl. No.: 12/309,488

(22) PCT Filed: Jul. 24, 2007
(86) PCT No.: PCT/EP2007/057620

§ 371 Date: Jan. 21, 2009

(30) Foreign Application Priority Data
Jul. 26, 2006 (DE) 10 2006 034 579.7

(51) Int. Cl. G01R 17/22; G01R 1/20; H03H 11/00; G01R 33/09

(52) U.S. Cl. 327/524; 324/126; 324/252

(57) ABSTRACT

At least one embodiment of the invention specifies a current-sensing apparatus and/or a method for its operation which is based on the current sensor provided being a GMR sensor in the form of a gradient sensor and on the gradient sensor, or a component which includes this gradient sensor, itself including a conductor section of a compensating circuit. As such, the current in the measurement circuit can be compensated for by a current in the compensating circuit and the compensating current can be evaluated as a measure of the electrical variable to be detected for the measurement circuit.

### PRIORITY STATEMENT

This application is the national phase under 35 U.S.C. § 371 of PCT International Application No. PCT/EP2007/057620 which has an International filing date of Jul. 24, 2007, which claims priority to German Application No. 10 2006 034 579.7 which has a filing date of Jul. 26, 2006, which designated the United States of America, the entire contents of which are hereby incorporated herein by reference.

### FIELD

At least one embodiment of the invention generally relates to a current-sensing apparatus with a magnetic field sensor functioning as a current sensor, in particular in a configuration as a GMR sensor. At least one embodiment of the invention furthermore relates to a corresponding method for current sensing.

### BACKGROUND

Current sensing apparatuses or current sensors are generally known. Thus, the current sensing is effected, in particular for the case of alternating current, in known approaches for example by way of inductive current transformers, so-called Hall sensors or, particularly for larger currents, by means of so-called Rogowski coils. By contrast, the potential-isolated sensing of direct currents is significantly more complex. Essentially the following methods are employed nowadays in this context: shunt resistor in conjunction with a differential amplifier, potential isolation (for example by means of optocouplers) and potential-free current supply. Alternative approaches are based on the use of a Hall current measuring system with a flux concentrator or on conventional AMR/GMR field sensors.

What is problematic in the shunt measurement is the direct electrical connection of the measurement points to the potential of the current-carrying line, that is to say of the respective current path in the respective measurement circuit. This requires evaluation electronics having both a potential-isolated current supply and a potential-isolated signal path for transmitting the measured values. Moreover, the shunt resistor lies directly in the current path, which can result in circuitry problems, for example, but with which at least a power loss is associated.

Current sensing using magnetic field sensors has the advantage of freedom from feedback, that is to say that for the current measurement it is not necessary to insert a series resistor in the manner of the shunt into the current path. Therefore, the need to interrupt the line is obviated, no power loss arises and no alteration of the line impedance arises. Furthermore, the use of magnetic field sensors is also associated with the advantage of the fundamental potential isolation, as also arises for example in the case of transformers.

What is problematic about the magnetic field measurement using magnetic field sensors, however, is the sensitivity thereof toward external and disturbance fields. This influence has to be combated by means of corresponding shielding measures or field concentrators. In this case, it is necessary to arrange the field sensor as close as possible to the line—for example a conductor track or the like—through which current flows, since the intensity of the magnetic field of a line through which current flows decreases greatly with distance. Moreover, in the case where the current to be measured has a large dynamic range, either the characteristic curve of the current sensor with its nonlinearity is traversed or the sensitivity has to be reduced to such a great extent that a severely noisy signal has to be evaluated in the case of small measurement currents.

EP-A-0 703 460 discloses a current sensor in which the current through part of a conductor is measured by means of a magnetic field sensor and a compensation current conductor. U.S. 2006/091993 A1 additionally describes a current sensor with a gradient sensor comprising a plurality of magnetic field sensor elements.

### SUMMARY

At least one embodiment of the invention accordingly resides in specifying a current-measuring apparatus and/or a corresponding method in which at least one of the abovementioned disadvantages are avoided or at least reduced with regard to their effect.

Accordingly, in at least one embodiment, in an apparatus for sensing at least one electrical variable, in particular the electric current, in a circuit with an MR sensor functioning as a current sensor, in particular in an embodiment as a GMR/AMR or TMR sensor—referred to in summarizing combination as GMR sensor hereinafter—it is provided, inter alia, that the GMR sensor comprises a conductor section of a compensation circuit.

Accordingly, in at least one embodiment, in a method for sensing at least one electrical variable in a circuit with an apparatus of the abovementioned type, it is provided that a signal supplied by the GMR sensor is evaluated in order to conduct a compensation current into the compensation circuit by means of an amplifier, wherein, as soon as the signal from the GMR sensor at least substantially disappears, the compensation current is evaluated as a measure of the electrical variable to be sensed, that is to say for example the electric current in the respective measurement circuit.

In this case, at least one embodiment of the invention is based on the insight that the abovementioned problem of dynamic range can be avoided by utilizing a compensation current. For this purpose, an inductance is arranged in such a way that it can generate a magnetic field which is superposed with the magnetic field of the current to be measured at the location of the current sensor. The resulting field is compensated for by impressing a compensation current into the inductance. The current sensor is thereby always operated in the region of an output signal zero point. The impressed compensation current then corresponds to the current to be measured or there is a known proportionality between the impressed compensation current and the current to be measured.

The GMR sensor functioning as a current sensor is embodied as a gradient sensor and outputs a signal proportional to a field difference. Influences of possible disturbance fields are thereby eliminated or reduced. Such a field difference is established when the GMR sensor is assigned to a conductor contour in the circuit which comprises at least two sections—first and second sections—and wherein a direction of a current flowing through the first section is opposite to the direction of the current in the second section. This conductor contour can also be conceived of in a simplified fashion as a substantially U-shaped contour in which the two sections mentioned above form the lateral limbs of such a U-shaped conductor course. The conductor contour is correspondingly also referred to just as “U-turn” for short hereinafter.

Furthermore, the conductor section which the GMR sensor comprises is also configured in the manner of a U-turn, that is to say that the conductor section comprises at least two segments—first and second segments—wherein a direction of a compensation current flowing through the conductor section in the first segment is opposite to the direction of the current in the second segment.

The compensation principle can be implemented particularly advantageously by the integration of the above-described U-turn, that is to say of a current loop, directly into a component having the GMR sensor. Owing to the spatial proximity of the integrated current loop to the GMR sensor which is then possible, only a very small compensation current is necessary to compensate even for large measurement currents. Above all, there is no need for an inductance in the form of a coil having a plurality of turns. One conductor loop, namely the U-turn, suffices. As a result of this, the overall arrangement can be realized very well in a planar monolithically integrable structure.

The advantage arises from the fact that the field recorded by the GMR sensor decreases at 1/x³. In an embodiment of the GMR sensor as a gradient sensor, the gradient recorded by the gradient sensor correspondingly decreases at 1/x⁴.

With the combination of GMR sensor and conductor section in one component, it is thus possible to realize a comparatively small distance between GMR sensor and conductor section. Moreover, with combination in one component, this results in a defined distance between the sensor and the conductor section. This distance, in addition to the distance to the circuit in which the electrical variable that is respectively of interest is intended to be measured, has to be known and taken as a basis in the evaluation of the measured values that respectively result. In the case of a small distance between GMR sensor and conductor section of the compensation circuit, the distance between GMR sensor and measurement circuit can be greater than the component-internal distance by a power of 4.

The measurement current and the compensation current then bring about an identical magnetic field at the location of the GMR sensor. Conversely, if the distance between GMR sensor and measurement circuit is chosen not to be so large, the compensation current can become smaller in accordance with the relations of the distances with respect to one another, such that only a comparatively small compensation current is required for compensating for the magnetic field of the measurement circuit.

With further preference, the MR sensor comprises a number of MR elements, that is to say, depending on the embodiment of the MR sensor as GMR/AMR or TMR sensor, GMR/AMR or respectively TMR elements—referred to in summarizing combination as GMR element hereinafter—, wherein each GMR element can be contact-connected individually.

This is because in the case of GMR elements that can be contact-connected individually, an offset voltage can be mirrored in its polarity by cyclically interchanging sensor pairs, that is to say two GMR elements in each case. By temporal addition of the output signals of a GMR sensor in a first configuration and then in a second configuration with cyclically interchanged sensor pairs with a correspondingly opposite offset voltage in each case, this measurement error can be compensated for.

This type of offset compensation requires a freely accessible array interconnection of the GMR elements, that is to say the individual contact-connectability thereof, which is complicated in the case of conventional realization with a plurality of circuits and, owing to the line routing, is also very sensitive to coupled-in disturbances. However, the GMR sensors can be applied directly on a silicon area of a circuit in the sense of vertical integration. The electrical connections can be realized as extremely short interconnects (sandwich arrangement).

For feeding the compensation current into the compensation circuit, an amplifier is preferably provided, the output signal of which is based on a signal supplied by the GMR sensor. Therefore, during operation, the GMR sensor senses both the magnetic field at the actual circuit, that is to say of the measurement circuit, and the magnetic field of the compensation circuit. As long as the magnetic field does not disappear, that is to say has not yet been compensated for by the compensation current, it is necessary for the magnitude of the compensation current to be adapted. This is effected by way of the amplifier. The driving of the amplifier is therefore based essentially on a closed-loop control that aims to control the magnetic field detected by the GMR sensor to zero by altering the magnitude of the compensation current.

The patent claims filed with the application are formulation proposals without prejudice for obtaining more extensive patent protection. The applicant reserves the right to claim even further combinations of features previously disclosed only in the description and/or drawings.

The example embodiment or each example embodiment should not be understood as a restriction of the invention. Rather, numerous variations and modifications are possible in the context of the present disclosure, in particular those variants and combinations which can be inferred by the person skilled in the art with regard to achieving the object for example by combination or modification of individual features or elements or method steps that are described in connection with the general or specific part of the description and are contained in the claims and/or the drawings, and, by way of combinable features, lead to a new subject matter or to new method steps or sequences of method steps, including insofar as they concern production, testing and operating methods.

References back that are used in dependent claims indicate the further embodiment of the subject matter of the main claim by way of the features of the respective dependent claim; they should not be understood as dispensing with obtaining independent protection of the subject matter for the combinations of features in the referred-back dependent claims. Furthermore, with regard to interpreting the claims, where a feature is concretized in more specific detail in a subordinate claim, it should be assumed that such a restriction is not present in the respective preceding claims.

Since the subject matter of the dependent claims in relation to the prior art on the priority date may form separate and independent inventions, the applicant reserves the right to make them the subject matter of independent claims or divisional declarations. They may furthermore also contain independent inventions which have a configuration that is independent of the subject matters of the preceding dependent claims.

### BRIEF DESCRIPTION OF THE DRAWINGS

An example embodiment of the invention is explained in greater detail below with reference to the drawings. Mutually corresponding objects or elements are provided with the same reference symbols in all the figures.

In the figures:

FIG. 1 shows a current-sensing apparatus,

FIG. 2 shows a gradient sensor as an example of a specific GMR sensor, and

FIG. 3 shows a component with a gradient sensor.

### DETAILED DESCRIPTION OF THE EXAMPLE EMBODIMENTS

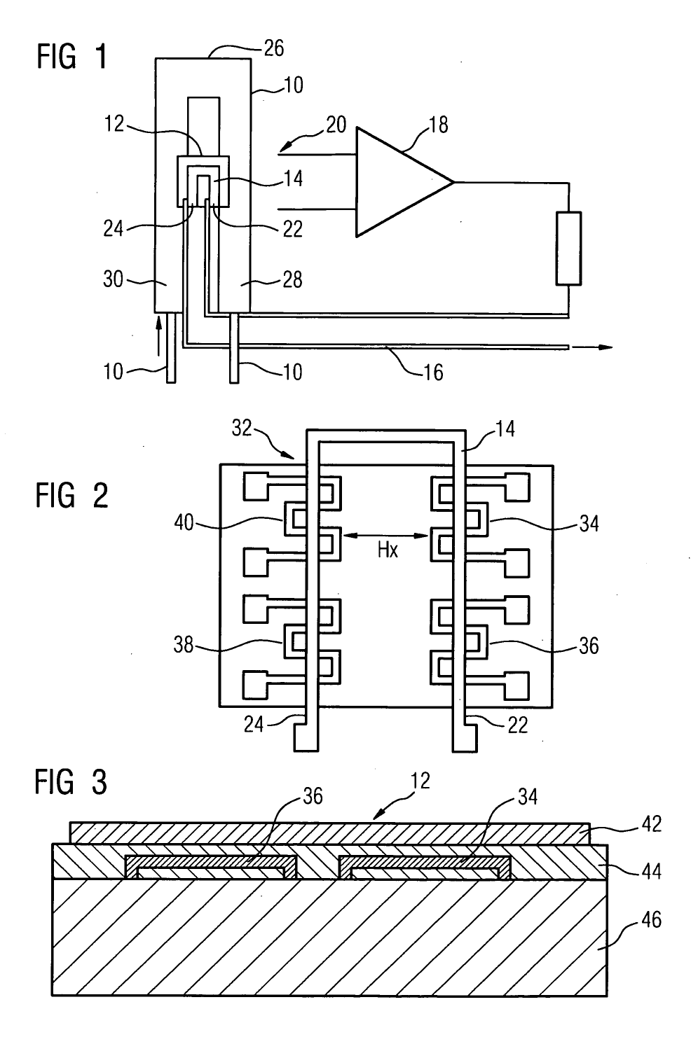

FIG. 1 shows a component 12 with a GMR sensor functioning as a current sensor. This is shown in schematically simplified form as an apparatus for sensing at least one electrical variable, in particular an electric current in a circuit 10 (measurement circuit). In the example embodiment shown, the GMR sensor, or the component 12, comprises a conductor section 14 of a compensation circuit 16.

For feeding the compensation current into the compensation circuit 16, an amplifier 18 is provided, which receives at least one input 20 a signal from the component 12 or the GMR sensor which the component comprises. The signal present at the input 20 of the amplifier 18 corresponds to the resulting magnetic field strength of the magnetic field generated by the current flowing through the measurement circuit 10 and the field strength that arises on account of the compensation current through the compensation circuit 16. If the magnetic field associated with the compensation current quenches, that is to say compensates for, the magnetic field from the measurement circuit 10, the signal at the input 20 disappears. The compensation current, that is to say the intensity of the compensation current, is then a measure of the current intensity in the measurement circuit 10.

As illustrated, the conductor section 14 of the compensation circuit 16 comprises at least two segments 22, 24—first and second segments 22, 24—, wherein a direction of a compensation current flowing through the conductor section 14 in the first segment 22 is opposite to the direction of the current in the second segment 24. The conductor section 14 is manifested overall as a “U-shaped” conductor section 14 and is correspondingly also referred to as a “U-turn” hereinafter.

The component 12 and/or the GMR sensor that the component 12 comprises is assigned to a conductor contour 26 in the measurement circuit 10 that corresponds to the conductor section 14. The conductor contour 26 comprises, analogously to the conductor section 14 in the compensation circuit 16, at least two sections 28, 30—first and second sections 28, 30—, wherein a direction of a current flowing through the first section 28, that is to say of the measurement current, is opposite to the direction of the measurement current in the second section 30.

Overall, the conductor section 14 of the compensation circuit 16 and the conductor contour 26 of the measurement circuit 10 form an inductance, wherein a gradient field is established in the conductor-free region between the two segments 22, 24, and between the two sections 28, 30, the gradient field being sensed by the component 12 and/or the GMR sensor that the component comprises, in its preferred embodiment as a gradient sensor.

FIG. 2 shows, in schematically simplified form, an illustration of a gradient sensor 32 as a GMR sensor such as is part of the component 12 (FIG. 1), for example. In accordance with the illustration, the gradient sensor 32 has four GMR elements 34, 36, 38, 40, wherein the GMR elements 34-40 are assigned respectively in pairs to the conductor section 14 of the compensation circuit 16 (FIG. 1). The gradient field, designated by “Hx” in the figure, forms between the segments 22, 24 of the U-shaped conductor section 14 of the compensation circuit 16, the gradient field being detected by the gradient sensor 32.

FIG. 3 shows, once again in simplified illustration, a section through the component 12 (cf. FIG. 1), wherein a layer of the component 12 that can be discerned only as the topmost layer 42 in the cross section illustrated is represented by the U-shaped conductor section 14 (also cf. FIG. 1 and FIG. 2). A passivation can be discerned as a further layer 44 between the topmost layer 42 and GMR elements 34, 36 arranged within the component 12. Beneath the further layer 44 is an ASIC, which is only represented as a third layer 46 and is provided for processing the data supplied by the GMR elements 34-40. The component 12 can be assigned overall (not illustrated) to the respective conductor contour 26 (FIG. 1) of a measurement circuit 10 (FIG. 1).

A proportionality factor for the weighting of the compensation current results from the defined distance between the conductor section 14, that is to say the first layer 42, and the GMR elements 34-40, on the one hand, and the GMR elements 34-40 and the conductor contour 26 of the measurement circuit, namely the thickness of the third layer 46. This is because, as described above, the magnetic field of a conductor through which current flows, that is to say either of the measurement circuit 10 or of the compensation circuit 16, decreases greatly with the distance from the conductor. The distance between the compensation circuit 16, that is to say in particular the conductor section 14, and the GMR elements 34-40 is significantly smaller than the distance between the GMR elements 34-40 and the conductor contour 26 of the measurement circuit 10.

Therefore, a comparatively smaller compensation current in the compensation circuit 16 also suffices to compensate for the magnetic field of the measurement circuit 10. If the signal of the gradient sensor 32 (FIG. 2) disappears, therefore, the compensation current then present corresponds to the current flowing in the measurement circuit 10 not directly but rather only taking as a basis the proportionality correlated with the abovementioned distances.

At least one embodiment of the present invention can thus be described briefly as follows: a current-sensing apparatus and a method for operating it are specified, based on the fact that the current sensor provided is a GMR sensor in an embodiment as a gradient sensor 32, and that the gradient sensor 32 or a component 12 comprising the gradient sensor 32 comprises, for its part, a conductor section 14 of a compensation circuit 16, such that the current in the measurement circuit can be compensated for by a current in the compensation circuit 16 and the compensation current can be evaluated as a measure of the electrical variable to be sensed with regard to the measurement circuit 10.

Example embodiments being thus described, it will be obvious that the same may be varied in many ways. Such variations are not to be regarded as a departure from the spirit and scope of the present invention, and all such modifications as would be obvious to one skilled in the art are intended to be included within the scope of the following claims.

1. An apparatus for sensing at least one electrical variable in a circuit, comprising:
a GMR sensor functioning as a current sensor,
the GMR sensor being embodied as a gradient sensor and including a conductor section of a compensation circuit, the conductor section including at least two segments, a direction of a compensation current flowing through the conductor section in a first of the at least two segments being opposite to a direction of the compensation current in a second of the at least two segments, wherein
the GMR sensor is assigned to a conductor contour in the circuit which includes at least two sections, a direction of a current flowing through a first of the at least two sections being opposite to a direction of the current in a second of the at least two sections.

2. The apparatus as claimed in claim 1,
wherein the GMR sensor is combined with the conductor section to form a component.

3. The apparatus as claimed in claim 1,
wherein the GMR sensor includes a plurality of GMR elements and wherein each GMR element is individually contact-connectable.

4. The apparatus as claimed in claim 1, further comprising:
an amplifier to feed the compensation current into the compensation circuit, an output signal of the compensation circuit being based on a signal supplied by the GMR sensor.

5. A method for sensing at least one electrical variable in a circuit, comprising:
evaluating the signal supplied by the GMR sensor, using an apparatus as claimed in claim 4, in order to conduct the compensation current into the compensation circuit by way of the amplifier; and
evaluating the compensation current, as soon as the signal from the GMR sensor at least substantially disappears, as a measure of the electrical variable to be sensed.

6.-8. (canceled)

9. The apparatus as claimed in claim 2, wherein the GMR sensor includes a plurality of GMR elements and wherein each GMR element is individually contact-connectable.

10. The apparatus as claimed in claim 2, further comprising:
an amplifier to feed the compensation current into the compensation circuit, an output signal of the compensation circuit being based on a signal supplied by the GMR sensor.

11. The apparatus as claimed in claim 3, further comprising:
an amplifier to feed the compensation current into the compensation circuit, an output signal of the compensation circuit being based on a signal supplied by the GMR sensor.

12. An apparatus, comprising:
a GMR sensor including a conductor section of a compensation circuit, the conductor section including at least two segments, a direction of a compensation current flowing through the conductor section in a first of the at least two segments being opposite to a direction of the compensation current in a second of the at least two segments; and
a conductor contour including at least two sections, a direction of a current flowing through a first of the at least two sections being opposite to a direction of the current in a second of the at least two sections.

13. The apparatus as claimed in claim 12, wherein the GMR sensor is combined with the conductor section to form a component.

14. The apparatus as claimed in claim 12, wherein the GMR sensor includes a plurality of GMR elements and wherein each GMR element is individually contact-connectable.

15. The apparatus as claimed in claim 13, wherein the GMR sensor includes a plurality of GMR elements and wherein each GMR element is individually contact-connectable.

16. The apparatus as claimed in claim 12, further comprising:
an amplifier to feed the compensation current into the compensation circuit, an output signal of the compensation circuit being based on a signal supplied by the GMR sensor.

17. The apparatus as claimed in claim 13, further comprising:
an amplifier to feed the compensation current into the compensation circuit, an output signal of the compensation circuit being based on a signal supplied by the GMR sensor.

18. The apparatus as claimed in claim 14, further comprising:
an amplifier to feed the compensation current into the compensation circuit, an output signal of the compensation circuit being based on a signal supplied by the GMR sensor.

19. The apparatus as claimed in claim 15, further comprising:
an amplifier to feed the compensation current into the compensation circuit, an output signal of the compensation circuit being based on a signal supplied by the GMR sensor.
